(19) United States
(12) Patent Application Publication
(10) Pub. No.: US 2025/0359006 A1
(43) Pub. Date: Nov. 20, 2025

(54) Connection Between Gate Structure And Source/Drain Feature

(71) Applicant: Taiwan Semiconductor Manufacturing Company, Ltd., Hsin-Chu (TW)

(72) Inventors: Feng-Ming Chang, Hsinchu County (TW); Yi-Hsun Chiu, Hsinchu County (TW)

(21) Appl. No.: 19/286,560

(22) Filed: Jul. 31, 2025

Related U.S. Application Data
(62) Division of application No. 17/892,779, filed on Aug. 22, 2022.

(51) Int. Cl. H10B 10/00

(52) U.S. Cl. CPC H10B 10/125

(57) ABSTRACT

An IC structure includes an SRAM cell. In an embodiment, the SRAM cell includes a channel region over a substrate, a source/drain feature coupled to the channel region, a gate structure intersecting the channel region, and a first contact feature electrically coupled to the source/drain feature and the gate structure. A portion of the first contact feature is disposed directly under the gate structure.

### PRIORITY DATA

The present application is a divisional application of U.S. patent application Ser. No. 17/892,779, filed Aug. 22, 2022, which is herein incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, aggressive scaling down of IC dimensions has resulted in densely spaced source/drain features and gate structures, and densely spaced source/drain contacts and gate vias. In some IC circuits (e.g., memory devices), a connection between a gate structure and a source/drain feature may be realized by various contact structures. For example, the gate structure may be electrically coupled to the source/drain feature via a butted contact (BCT) formed thereover. With ever-decreasing device sizes, the butted contact suffers from limited contact surfaces for connection between the gate structure and the source/drain contact, which may lead to high contact resistance and/or poor connection. Also, a reduced space between the butted contact and its neighboring conductive features (e.g., source/drain contact vias, metal lines) may lead to current leakage, which also increases power consumption and if sufficiently large can also cause complete circuit failure. Therefore, while existing gate-to-source/drain connections may be generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a diagrammatic plan view of an IC chip, in portion or entirety, according to various aspects of the present disclosure.

FIGS. 1B and 1C are diagrammatic plan views of an array of memory cells, such as static random-access memory (SRAM) cells, in portion or entirety, according to various aspects of the present disclosure.

FIG. 2 is a circuit diagram of a memory cell, such as an SRAM cell, that can be implemented in the IC chip of FIG. 1, according to various aspects of the present disclosure.

FIG. 3A is a layout of a memory cell, such as an SRAM cell, in portion or entirety, according to various aspects of the present disclosure.

FIGS. 3B, 3C, and 3D are various top, plan views of various layers of the memory cell of FIG. 3A, in portion or entirety, according to various aspects of the present disclosure.

FIG. 4 illustrates a flowchart of an exemplary method for fabricating a backside butted contact of an SRAM cell, according to various embodiments of the present disclosure.

FIGS. 5A, 6A, 7A, 8A, 9A, 10A and 11A illustrate fragmentary cross-sectional views of a workpiece taken along line A-A as shown in FIG. 3A during various fabrication stages in the method of FIG. 4, according to various aspects of the present disclosure.

FIGS. 5B, 6B, 7B, 8B, 9B, 10B and 11B illustrate fragmentary cross-sectional views of the workpiece taken along line B-B as shown in FIG. 3A during various fabrication stages in the method of FIG. 4, according to various aspects of the present disclosure.

FIGS. 12A and 12B illustrate fragmentary cross-sectional views of an alternative workpiece taken along line A-A and B-B as shown in FIG. 3A, respectively, according to various aspects of the present disclosure.

FIG. 13 illustrates a flowchart of an alternative method for fabricating a backside butted contact of an SRAM cell, according to various embodiments of the present disclosure.

FIGS. 14A, 15A, 16A, and 17A illustrate fragmentary cross-sectional views of a workpiece taken along line A-A as shown in FIG. 3A during various fabrication stages in the method of FIG. 13, according to various aspects of the present disclosure.

FIGS. 14B, 15B, 16B, and 17B illustrate fragmentary cross-sectional views of a workpiece taken along line B-B as shown in FIG. 3A during various fabrication stages in the method of FIG. 13, according to various aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

Multi-gate devices, such as fin field-effect transistors (FinFETs) and multi-bridge-channel (MBC) transistors, have been introduced in an effort to improve gate control by increasing gate-channel coupling, reduce OFF-state current, and reduce short-channel effects (SCEs). A FinFET has an elevated channel wrapped by a gate on more than one side (for example, the gate wraps a top and sidewalls of a “fin” of semiconductor material extending from a substrate). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor. The channel region of an MBC transistor may be formed from nanowires, nanosheets, or other nanostructures and for that reasons, an MBC transistor may also be referred to as a nanowire transistor or a nanosheet transistor. The three-dimensional structure of the multi-gate devices allows them to be aggressively scaled while maintaining gate control and mitigating SCEs.

IC manufacturing process flow may be typically divided into three categories: front-end-of-line (FEOL) processes, middle-end-of-line (MEOL) processes, and back-end-of-line (BEOL) processes. FEOL processes generally encompasses processes related to fabricating IC devices, such as transistors. For example, FEOL processes may include forming isolation features, gate structures, and source/drain features. Source/drain feature(s) may refer to a source or a drain, individually or collectively dependent upon the context. MEOL processes generally encompasses processes related to fabricating contacts to conductive features of the IC devices, such as gate vias to the gate structures and/or source/drain contacts to the source/drain features. BEOL processes generally encompasses processes related to fabricating a multilayer interconnect (MLI) structure that interconnects IC features fabricated by FEOL and MEOL process, thereby enabling operation of the IC devices. Features fabricated by FEOL processes may be referred to as FEOL features. Features fabricated by MEOL processes may be referred to as MEOL features. Features fabricated by BEOL processes may be referred to as BEOL features.

Some IC devices include a connection between FEOL features. For example, some static random-access memory (SRAM) cells include an electrical connection between a gate structure of one transistor and a source/drain feature of another transistor. In some existing technologies, MEOL or even BEOL contact features are fabricated to achieve such a connection. As described above, aggressive scaling down of IC dimensions has resulted in densely spaced transistors, which would result in densely spaced MEOL features and densely spaced BEOL features. The challenges in fabricating densely spaced MEOL features and densely spaced BEOL features may limit increase in transistor density. The close proximity among the source/drain contacts, gate contact vias, butted contacts, and metal lines may also increase parasitic capacitance among them and may lead to current leakage.

The present disclosure provides integrated circuit structures and methods for introducing a backside butted contact that is configured to provide electrical connection between a gate structure of one transistor and a source/drain feature of another transistor instead of forming a frontside butted contact. In an embodiment, an integrated circuit structure includes a channel region over a substrate, a source/drain feature coupled to the channel region, a gate structure intersecting the channel region, and a butted contact vertically overlapped with the source/drain feature and electrically coupled to the source/drain feature, where the butted contact is in direct contact with a bottom surface of the gate structure. Forming the butted contact under the source/drain feature would increase a contact area between the butted contact and the gate structure and a contact area between the butted contact and the source/drain feature, thereby providing a better connection. Forming the butted contact under the source/drain feature would release room that would be otherwise occupied by a frontside butted contact, thus design flexibility of metal lines that are disposed over the source/drain feature and adjacent to the frontside butted contact may be increased. Therefore, leakage or short issue may be alleviated.

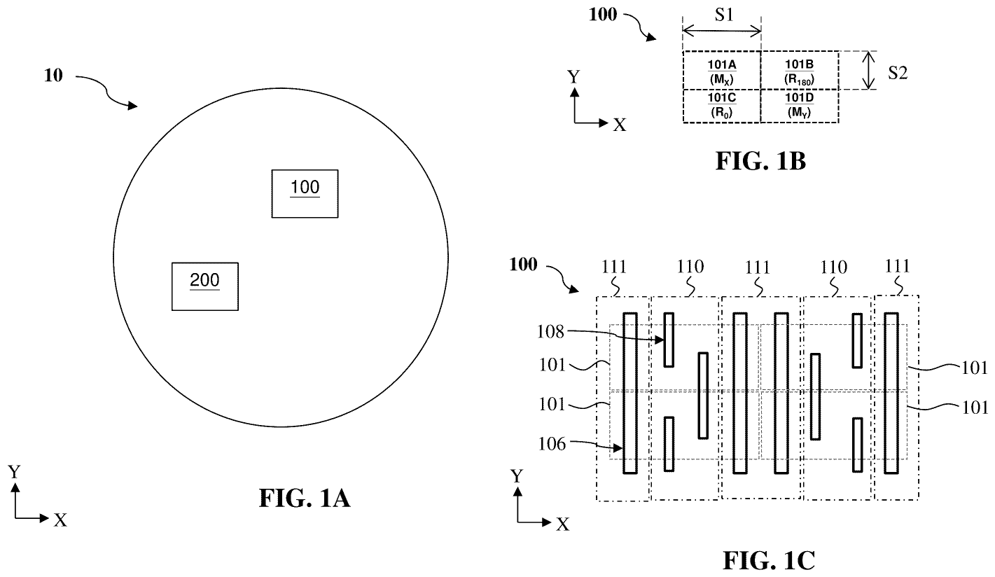

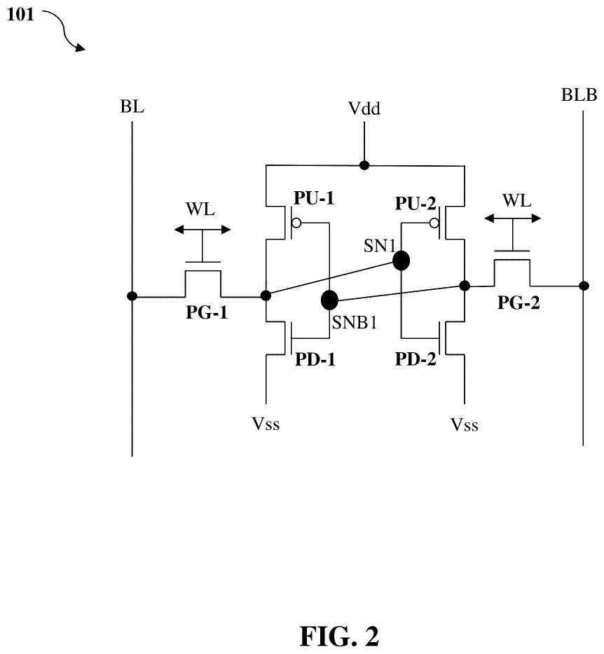

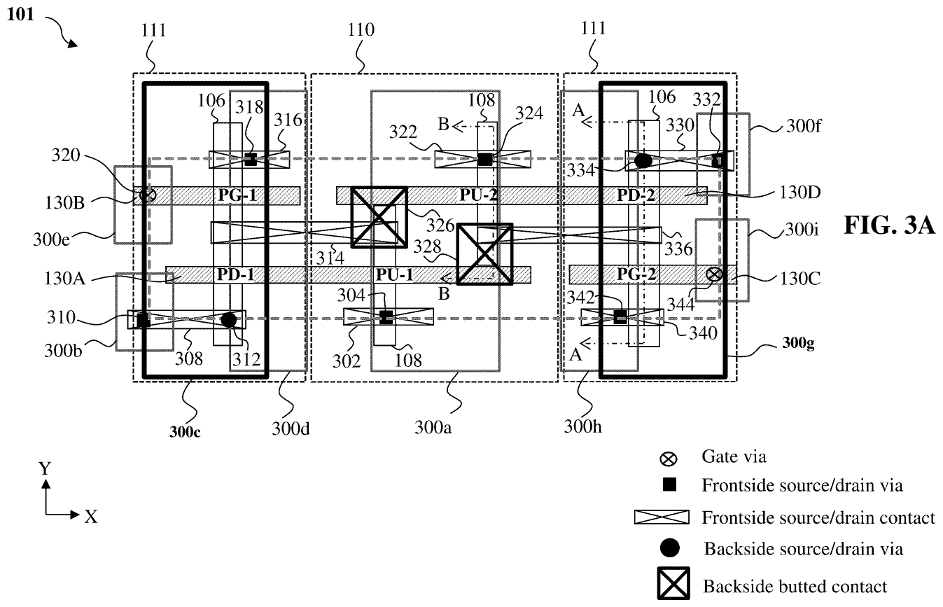

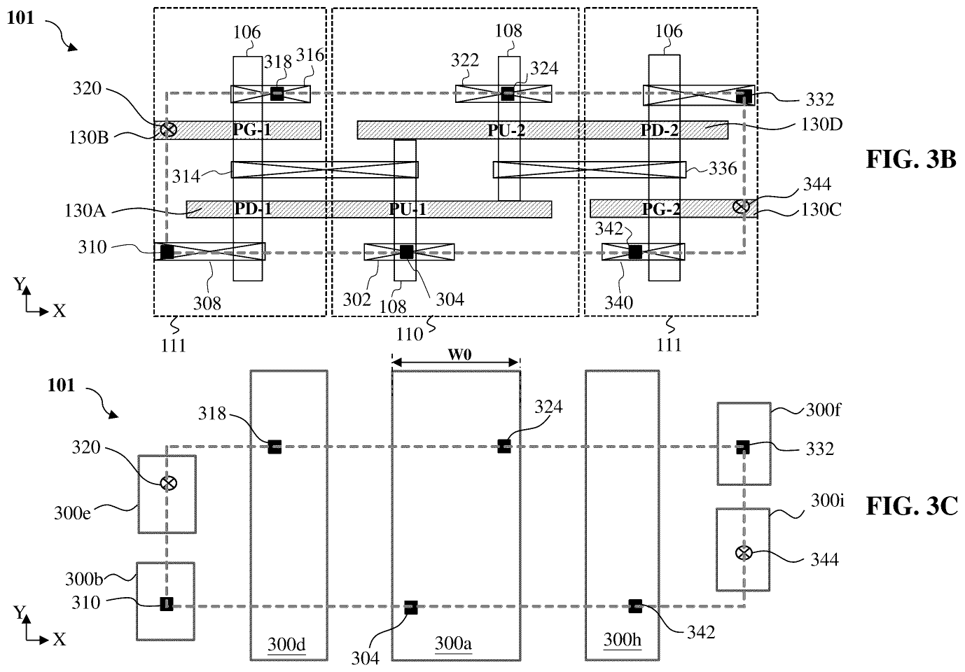

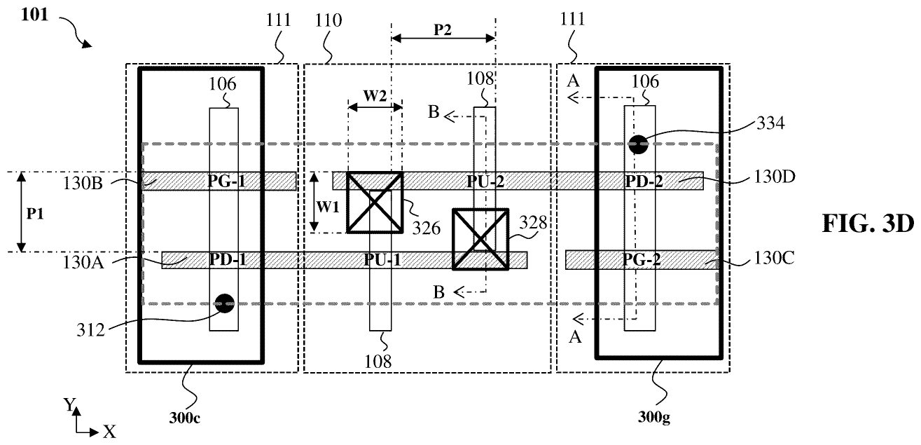

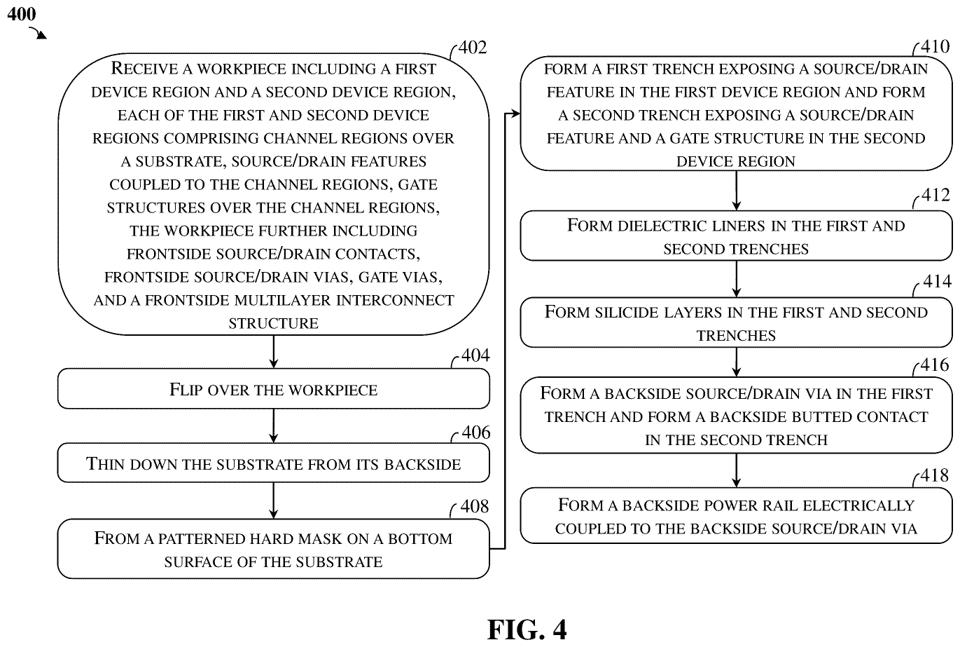

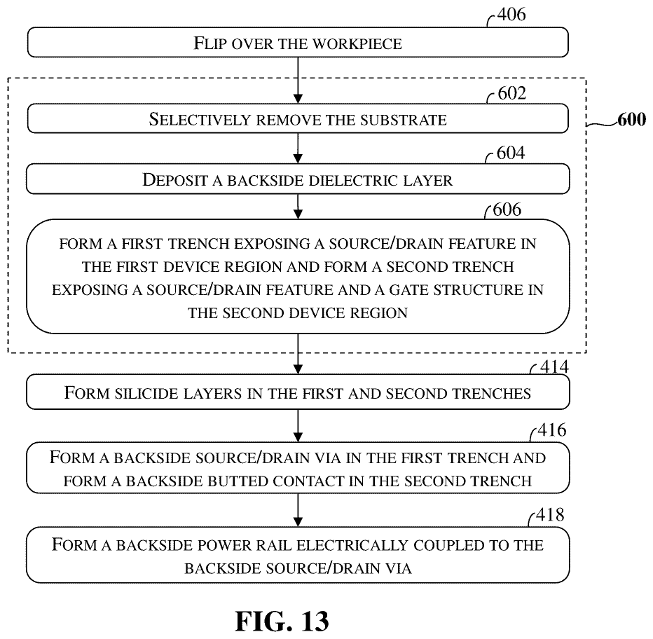

The various aspects of the present disclosure will now be described in more detail with reference to the figures. In that regard, FIG. 1A is a diagrammatic plan view of an exemplary IC chip. FIGS. 1B and 1C are diagrammatic plan views of an array of memory cells, such as static random-access memory (SRAM) cells, in portion or entirety, according to various aspects of the present disclosure. FIG. 2 is a circuit diagram of an SRAM cell that can be implemented in the IC chip of FIG. 1. FIG. 3A is a layout of an SRAM cell, in portion or entirety, according to various aspects of the present disclosure. FIGS. 3B, 3C, and 3D are various top, plan views of various layers of the SRAM cell of FIG. 3A, in portion or entirety, according to various aspects of the present disclosure. FIG. 4 is a flow chart illustrating method 400 of forming a backside butted contact. FIG. 13 is a flow chart illustrating another alternative method 600 for forming a backside butted contact. Method 400 and method 600 are described below in conjunction with FIGS. 3A-3D, 5A-12A, 5B-12B, and 14A-17A and 14B-17B. Method 400 and method 600 are merely examples and are not intended to limit the present disclosure to what is explicitly illustrated therein. Additional steps may be provided before, during, and/or after the method 400 and method 600, and some steps described can be replaced, eliminated, or moved around for additional embodiments of the method. Not all steps are described herein in detail for reasons of simplicity. Because the workpiece 500/700 will be fabricated into an integrated circuit structure or semiconductor structure upon conclusion of the fabrication processes, the workpiece 500/700 may be referred to as the integrated circuit structure 500/700 or semiconductor structure 500/700 as the context requires. For avoidance of doubts, the X, Y and Z directions in FIGS. 3A-3D, 5A-12A, 5B-12B, 14A-17A and 14B-17B are perpendicular to one another and are used consistently throughout the present disclosure. Throughout the present disclosure, like reference numerals denote like features unless otherwise excepted. In the present disclosure, frontside features (e.g., frontside source/drain contacts, frontside source/drain vias) may be referred to as features that are formed over a top surface of a workpiece, and backside features (e.g., backside butted contact) may be referred to as features that are formed under a bottom surface of the workpiece.

Referring to FIG. 1A, the present disclosure provides an IC structure 10 formed over a semiconductor substrate and includes at least an array 100 of memory cells. The array 100 may include static random-access memory (SRAM) cells, dynamic random-access memory (DRAM) cells, non-volatile random-access memory (NVRAM) cells, flash memory cells, other suitable memory cells, or combinations thereof. The IC structure 10 may further include a number of other components, such as an array 200 of standard logic (STD) cells configured to provide various standard logic devices, such as inverter, AND, NAND, OR, XOR, NOR, other suitable devices, or combinations thereof. Additionally, the IC structure 10 may include various passive and active microelectronic devices, such as resistors, capacitors, inductors, diodes, bipolar transistors, high voltage transistors, high frequency transistors, other suitable devices, or combinations thereof. Additional features can be added to the IC structure 10 and some of the features described below can be replaced, modified, or eliminated in other embodiments of the IC structure 10.

In the present embodiments, referring to FIG. 1B, the array 100 includes a number of SRAM cells 101A, 101B, 101C, and 101D, which generally provide memory or storage capable of retaining data when power is applied. As such, the array 100 is hereafter referred to as SRAM array 100. In the present embodiments, each SRAM cell 101A-101D includes one or more GAA transistors to be discussed in detail below.

In the present embodiments, still referring to FIG. 1B, the SRAM cells 101A, 101B, 101C, and 101D, together defining a two-by-two grid, exhibit mirror and/or rotational symmetry with respect to each other. For example, using the SRAM cell 101C as a reference (denoted “R₀”), a layout of the SRAM cell 101A (denoted “M_{X}”) is a mirror image of a layout of the SRAM cell 101C with respect to the X-axis. Similarly, a layout of the SRAM cell 101B is a mirror image of the layout of the SRAM cell 101A, and a layout of the SRAM cell 101D (denoted “M_{Y}”) is a mirror image of the layout of the SRAM cell 101C, both with respect to the Y-axis. In other words, the layout of the SRAM cell 101B (denoted “R₁₈₀”) is symmetric to the layout of the SRAM 101C by a rotation of 180 degrees about a geometric center of the grid, which is defined as an intersection point of an imaginary line bisecting the rectangular grid along the Y-axis and an imaginary line bisecting the rectangular grid along the X-axis. Furthermore, in the depicted embodiments, the SRAM cells 101A-101D are substantially the same in size, i.e., having substantially the same horizontal (long) pitch S1 along the X-axis and a vertical (short) pitch S2 along the Y-axis. As such, each SRAM cells 101A-101D may hereafter be referred to as the SRAM cell 101 for purposes of simplicity.

Referring to FIG. 1C, each SRAM cell 101 is configured to include p-type three-dimensional fin-like active regions 106 (hereafter referred to as p-type fins 106) each disposed in a p-type doped region 111 (hereafter referred to as p-well 111) and n-type three-dimensional fin-like active regions 108 (hereafter referred to as n-type fins 108) each disposed in a n-type doped region 110 (hereafter referred to as n-well 110), which is interposed between two p-wells 111. The p-type fins 106 and the n-type fins 108 are oriented lengthwise along Y-axis and spaced from each other along X-axis, which is substantially perpendicular to the Y-axis. As will be discussed in detail below, each p-type fin 106 includes a first set of vertically stacked semiconductor layers configured to provide channel regions of n-type GAA transistors, and each n-type fin 108 includes a second set of vertically stacked semiconductor layers configured to provide channel regions of P-type GAA transistors. The second set of vertically stacked semiconductor layers may differ from the first set of vertically stacked semiconductor layers in at least one dimension along the X-axis. In other words, a channel length of the n-type GAA transistors may differ from a channel length of the p-type GAA transistors. Various SRAM cells 101 may be configured for similar applications, such as a high-speed application, a low-power application, other suitable applications, or combinations thereof. Alternatively, different SRAM cells 101 may be configured for different applications and designed with different specifications (e.g., dimensions, layout designs, etc.) accordingly. Various aspects and embodiments of the SRAM cell 101 are discussed in detail below.

FIG. 2 illustrates an exemplary circuit schematic for a single-port SRAM cell (e.g., 1-bit SRAM cell) 101. The single-port SRAM cell 101 includes pull-up transistors PU-1, PU-2; pull-down transistors PD-1, PD-2; and pass-gate transistors PG-1, PG-2. As show in the circuit diagram, transistors PU-1 and PU-2 are p-type transistors, and transistors PG-1, PG-2, PD-1, and PD-2 are n-type transistors. Since the SRAM cell 101 includes six transistors in the illustrated embodiment, it may also be referred to as a 6T SRAM cell.

The drains of pull-up transistor PU-1 and pull-down transistor PD-1 are coupled together, and the drains of pull-up transistor PU-2 and pull-down transistor PD-2 are coupled together. Transistors PU-1 and PD-1 are cross-coupled with transistors PU-2 and PD-2 to form a first data latch. The gates of transistors PU-2 and PD-2 are coupled together and to the drains of transistors PU-1 and PD-1 to form a first storage node SN1, and the gates of transistors PU-1 and PD-1 are coupled together and to the drains of transistors PU-2 and PD-2 to form a complementary first storage node SNB1. Sources of the pull-up transistors PU-1 and PU-2 are coupled to power voltage Vdd, and the sources of the pull-down transistors PD-1 and PD-2 are coupled to a voltage Vss, which may be an electrical ground in some embodiments. In some embodiments, gates of transistors PU-2 and PD-2 are coupled to the drains of transistors PU-1 and PD-1 by a first butted contact, and the gates of transistors PU-1 and PD-1 are coupled to the drains of transistors PU-2 and PD-2 by a second butted contact. Detailed of the first and second butted contacts will be described below with reference to FIGS. 3A, 3D, and 4. The first storage node SN1 of the first data latch is coupled to bit line BL through pass-gate transistor PG-1, and the complementary first storage node SNB1 is coupled to complementary bit line BLB through pass-gate transistor PG-2. The first storage node SN1 and the complementary first storage node SNB1 are complementary nodes that are often at opposite logic levels (logic high or logic low). Gates of pass-gate transistors PG-1 and PG-2 are coupled to a word line WL.

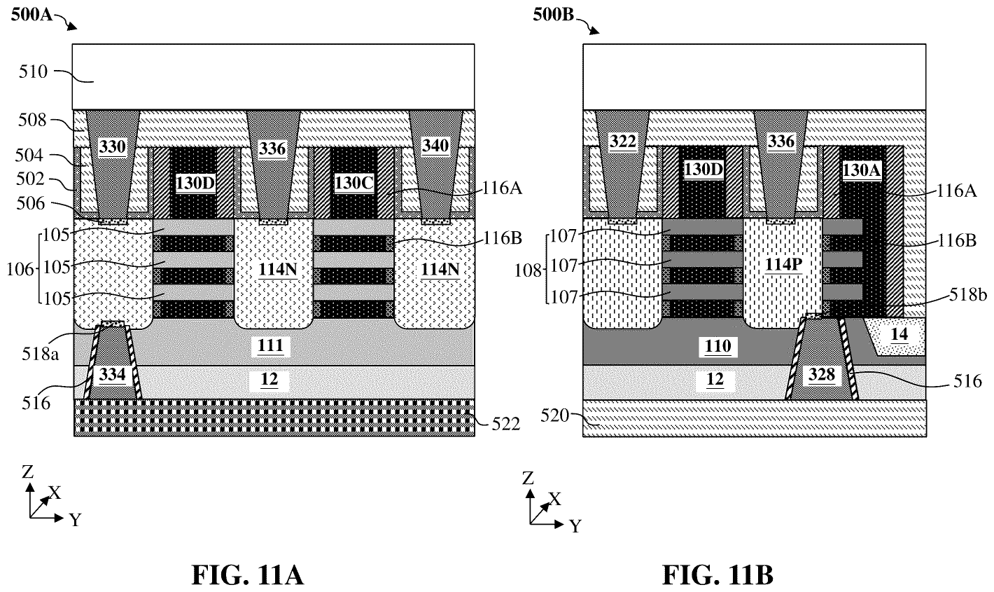

FIG. 3A is a layout of the SRAM cell 101, in portion or entirety, according to various aspects of the present disclosure. FIGS. 3B, 3C, and 3D are various top, plan views of various layers of the SRAM cell 101 of FIG. 3A, in portion or entirety, according to various aspects of the present disclosure. More specifically, FIG. 3B depicts a top, plan view of source/drain features and gate structures of transistors, frontside source/drain contacts, frontside gate vias, and frontside source/drain vias disposed on the frontside source/drain contacts, in portion or entirety, of the SRAM cell 101. FIG. 3C depicts a top, plan view of frontside gate vias, frontside source/drain vias disposed on the source/drain contacts, and metal lines/contacts disposed on the frontside gate vias or the frontside source/drain vias, in portion or entirety, of the SRAM cell 101. FIG. 3D depicts a top, plan view of source/drain features and gate structures of transistors, backside source/drain vias disposed under source/drain features, and backside butted contacts disposed under source/drain features and gate structures, and metal lines disposed under the source/drain features, in portion or entirety, of the SRAM cell 101. Additional features can be added to the SRAM cell 101 and some of the features described below can be replaced, modified, or eliminated in other embodiments of the SRAM cell 101. FIG. 11A illustrates a fragmentary cross-sectional view of the SRAM cell 101 taken along line A-A as shown in FIG. 3A. FIG. 11B illustrates a fragmentary cross-sectional view of the SRAM cell 101 taken along line B-B as shown in FIG. 3A.

In the present embodiments, referring to FIGS. 3A, 3B, 3C, 3D and FIGS. 11A and 11B, the SRAM cell 101 (as a portion of the IC structure 10) is formed over a substrate (or a wafer) 12 having a number of p-wells (p-type doped regions) 111 and n-wells (n-type doped regions) 110 formed therein (and/or thereover) according to various design requirements of the SRAM array 100. In the depicted embodiments, the portion of the substrate 12 within each SRAM cell 101 (e.g., the SRAM cell 101C as depicted in FIG. 3A) includes an n-well 110 disposed between two p-wells 111. The n-well 110 is configured to provide at least one p-type field-effect transistor (PFET), such as a pull-up transistor, and each p-well 111 is configured to provide at least one n-type field-effect transistor (NFET), such as a pull-down transistor or a pass-gate transistor. In some embodiments, the substrate 12 may include additional doped regions configured to provide one or more transistors according to design requirements of the SRAM array 100. The SRAM cell 101 further includes isolation structures 14 (shown in FIG. 11B) disposed over the substrate 12 to electrically separate various active regions formed over the substrate 12. In the present embodiments, the isolation structures 14 include shallow trench isolation (STI) features. In the present embodiments represented in FIG. 3A, each SRAM cell 101 includes two p-type fins 106 each disposed in a p-type well 111 and two n-type fins 108 disposed in an n-type well 110 interposing between the two p-type wells 111.

In the present embodiments represented in FIGS. 11A-11B, each p-type fin 106 includes a stack of semiconductor layers 105; similarly, and each n-type fin 108 includes a stack of semiconductor layers 107. In the depicted embodiments, the semiconductor layers 105 and 107 are generally oriented lengthwise along the Y-axis and stacked vertically along the Z-axis. Furthermore, each stack of the semiconductor layers 105 interposes n-type source/drain (S/D) features 114N, and each stack of the semiconductor layers 107 interposes p-type S/D features 114P.

Each of the channel layers 105 and 107 may include Si, Ge, SiC, SiGe, GeSn, SiGeSn, SiGeCSn, other suitable semiconductor materials, or combinations thereof. In the present embodiments, each of the semiconductor layers 105 and 107 includes Si in the form of a nanosheet, a nanowire (e.g., a nanowire having a hexagonal cross-section), a nanorod (e.g., a nanorod having a square or round cross-section), or other suitable configurations. In some embodiments, the p-type fin 106 and the n-type fin 108 each include two to ten channel layers 105 and 107, respectively. For example, the p-type fin 106 and the n-type fin 108 may each include three channel layers 105 and three channel layers 107, respectively. Of course, the present disclosure is not limited to such configurations and the number of semiconductor layers may be tuned according to design requirements for the IC structure 10.

Still referring to FIGS. 3A, 3B, 3C, 3D and FIGS. 11A and 11B, each SRAM cell 101 further includes gate structures, such as gate structures 130A, 130B, 130C, and 130D, oriented lengthwise along the X-axis and disposed over the p-type fins 106 and/or the n-type fins 108 to form various transistors. Each gate structure 130A-130D traverses a channel region of a p-type fin 106 and/or an n-type fin 108. In the present embodiments, the semiconductor layers 105 are suspended in (or wrapped around by) the gate structures 130A-130D (e.g., the gate structure 130D and gate structure 130C as depicted in FIG. 11A) to form n-type GAA transistors, and the semiconductor layers 107 are suspended in (or wrapped around by) one of the gate structures 130A-130D (e.g., the gate structures 130D and 130A depicted in FIG. 11B) to form P-type GAA transistors. In other words, each stack of the semiconductor layers 105 engages with a portion of the gate structure 130A-130D to form a channel region of a n-type GAA transistor, and each stack of the semiconductor layers 107 engages with a portion of the gate structure 130A-130D to form a channel region of a p-type GAA transistor. As such, the semiconductor layers 105 are hereafter referred to as channel layers 105, and the semiconductor layers 107 are hereafter referred to as channel layers 107 for purposes of clarity.

In the depicted embodiments, referring to FIG. 3A as an example, portions of the gate structure 130A engage with the first p-type fin 106 and a first n-type fin 108 to form a pull-down transistor PD-1 and a pull-up transistor PU-1, respectively; a portion of the gate structure 130B engages with the first p-type fin 106 to form a pass-gate transistor PG-1; a portion of the gate structure 130C engages with the second p-type fin 106 to form a pass-gate transistor PG-2; and portions of the gate structure 130D engage with the second p-type fin 106 and the second n-type fin 108 to form a pull-down transistor PD-2 and a pull-up transistor PU-2, respectively. In some embodiments, the PU-1 and the PU-2 are configured as p-type transistors, while the PD-1, the PD-2, the PG-1, and the PG-2 are configured as n-type transistors.

In embodiments represented in FIGS. 3A-3D, gate of the PU-1 interposes a source (hereafter interchangeably referred to as a source node or a source terminal), which is electrically coupled to a power supply voltage Vdd by way of a frontside source/drain contact 302 and a frontside source/drain via 304 formed on the frontside source/drain contact 302. The frontside source/drain contact 302 is formed over the source of the PU-1. In an embodiment, the frontside source/drain via 304 is located between, physically contacts, and connects the frontside source/drain contact 302 to a Vdd line 300a that is electrically connected to the power supply voltage Vdd.

Gate of the PD-1 interposes a source, which is electrically coupled to a power supply voltage Vss by way of a frontside source/drain contact 308 and a frontside source/drain via 310 formed on the frontside source/drain contact 308. In the present embodiments, gate of the PU-1 and gate of the PD-1 are portions of the gate structure 130A. The frontside source/drain contact 308 is formed over the source of the PD-1. In an embodiment, the frontside source/drain via 310 is located between, physically contacts, and connects the frontside source/drain contact 308 to a Vss line 300b that is electrically connected to the power supply voltage Vss. In some embodiments, to reduce a parasitic resistance of the SRAM cell 101, source of the PD-1 is further electrically coupled to a power supply voltage Vss′ by way of a backside source/drain via 312. The backside source/drain via 312 may be disposed directly under the source of the PD-1 and between the source of the PD-1 and a Vss′ line 300c that is electrically connected to the power supply voltage Vss′. The backside source/drain via 312 may be spaced apart from the source of the PD-1 by a silicide layer (not shown). In an embodiment, the power supply voltage Vss′ is equal to the power supply voltage Vss.

Drain of the PD-1 and drain of the PU-1 are electrically connected by a source/drain contact 314. Source of the PG-1 shares the drain of the PD-1. That is, source of the PG-1 and drain of the PD-1 are formed from a same epitaxial source/drain feature. In other words, source of the PG-1 is also electrically coupled the drain of the PU-1 by the source/drain contact 314. Drain of the PG-1 is electrically coupled to a bit line contact 300d by way of a frontside source/drain contact 316 and a frontside source/drain via 318 formed on the frontside source/drain contact 316. The bit line contact 300d is electrically connected to the bit line BL. The frontside source/drain contact 316 is formed over the drain of the PG-1. In an embodiment, the frontside source/drain via 318 is located between, physically contacts, and connects the frontside source/drain contact 316 to the bit line contact 300d. Gate of the PG-1 is electrically coupled to a word line contact 300e by way of a gate via 320 formed on the gate structure 130B. In an embodiment, the gate via 320 is located between, physically contacts, and connects gate structure 130B to the word line contact 300e. The word line contact 300e is electrically connected to the word line WL.

Gate of the PU-2 interposes a source, which is electrically coupled to the power supply voltage Vdd by way of a frontside source/drain contact 322 and a frontside source/drain via 324 formed on the frontside source/drain contact 322. The frontside source/drain contact 322 is formed over the source of the PU-2. In an embodiment, the frontside source/drain via 324 is located between, physically contacts, and connects the frontside source/drain contact 322 to the Vdd line 300a that is electrically connected to the power supply voltage Vdd. Gate of the PU-2 is electrically connected to drain of the PU-1 by a butted contact 326, and gate of the PU-1 is electrically connected to drain of the PU-2 by a butted contact 328. In the present embodiments, to increase contact areas between the butted contacts and the drains and contact areas between the butted contacts and the gate structures, increase the design flexibility of metal lines (e.g., the Vdd line 300a) that are disposed over the drains and adjacent to those frontside butted contacts, and alleviate leakage and short issue, the butted contact 326 and the butted contact 328 are formed under the drains and gates of the PU-1 and PU-2. The butted contact 326/328 may be referred to as a backside butted contact 326/328 or backside connection 326/328. By forming the butted contacts 326/328 under the drains and gates of the PU-1 and PU-2, leakage and short issue may be alleviated. In addition, design flexibility of the Vdd line 300a may be increased and design flexibility of the bit line contact 300d may be increased accordingly. In the present embodiments, substantially an entirety of the Vdd line 300a has a substantially uniform width W0 (shown in FIG. 3). In embodiments presented in FIG. 3A, the Vdd line 300a is formed over and vertically overlapped with the backside butted contacts 326 and 328. The butted contact 326/328 has a width W1 (shown in FIG. 3D) along the Y-axis. A ratio of the width W1 to a gate pitch P1 of the SRAM cell 101 may be between about ⅙ and about 1. The butted contact 326/328 has a width W2 along the X-axis. A ratio of the width W2 to an active region pitch P2 of the SRAM cell 101 may be between about 1 and about 2. The width W1 and width W2 are selected such that there are enough contact areas between the butted contact 326/328 and the drains and gates of the PU-1 and PU-2 without inducing significant parasitic capacitance between the butted contact 326/328 and its surrounding features. Methods for forming the butted contact (e.g., the butted contact 328) will be described with reference to FIGS. 4, 5A-12A, 5B-12B and FIGS. 13, 14A-17A, and 14B-17B.

Still referring to FIGS. 3A-3D, gate of the PD-2 interposes a source, which is electrically coupled to the power supply voltage Vss by way of a frontside source/drain contact 330 and a frontside source/drain via 332 formed on the frontside source/drain contact 330. The frontside source/drain contact 330 is formed over the source of the PD-2. In an embodiment, the frontside source/drain via 332 is located between, physically contacts, and connects the frontside source/drain contact 330 to a Vss line 300f that is electrically connected to the power supply voltage Vss. In some embodiments, to reduce a parasitic resistance of the SRAM cell 101, source of the PD-2 is further electrically coupled to a power supply voltage Vss′ by way of a backside source/drain via 334. The backside source/drain via 334 may be disposed directly under the source of the PD-2 and between the source of the PD-2 and a Vss′ line 300g that is electrically connected to the power supply voltage Vss′. The backside source/drain via 334 may be spaced apart from the source of the PD-2 by a silicide layer (not shown). In an embodiment, the power supply voltage Vss′ is equal to the power supply voltage Vss. Drain of the PD-2 and drain of the PU-2 are electrically connected by a source/drain contact 336. Gate of the PU-2 and gate of the PD-2 are portions of the gate structure 130D.

Still referring to FIGS. 3A-3D, source of the PG-2 is electrically coupled to a bit line contact 300h by way of a frontside source/drain contact 340 and a frontside source/drain via 342 formed on the frontside source/drain contact 340. The bit line contact 300h is electrically connected to receive a complementary bit line (BLB). The frontside source/drain contact 340 is formed over the source of the PG-2. In an embodiment, the frontside source/drain via 342 is located between, physically contacts, and connects the frontside source/drain contact 340 to the bit line contact 300h. Gate of the PG-2 is electrically coupled to a word line contact 300i by way of a gate via 344 formed on the gate structure 130C. In an embodiment, the gate via 344 is located between, physically contacts, and connects gate structure 130C to the word line contact 300i. The word line contact 300i is electrically connected to the word line WL. Although not shown, in some embodiments, the word line WL may be generally oriented parallel to the lengthwise direction of the gate structures 130A-130D. Drain of the PG-2 shares the drain of the PD-2. That is, drain of the PG-2 and drain of the PD-2 are formed from a same epitaxial source/drain feature. In other words, drain of the PG-2 is also electrically coupled the drain of the PU-2 by the source/drain contact 336.

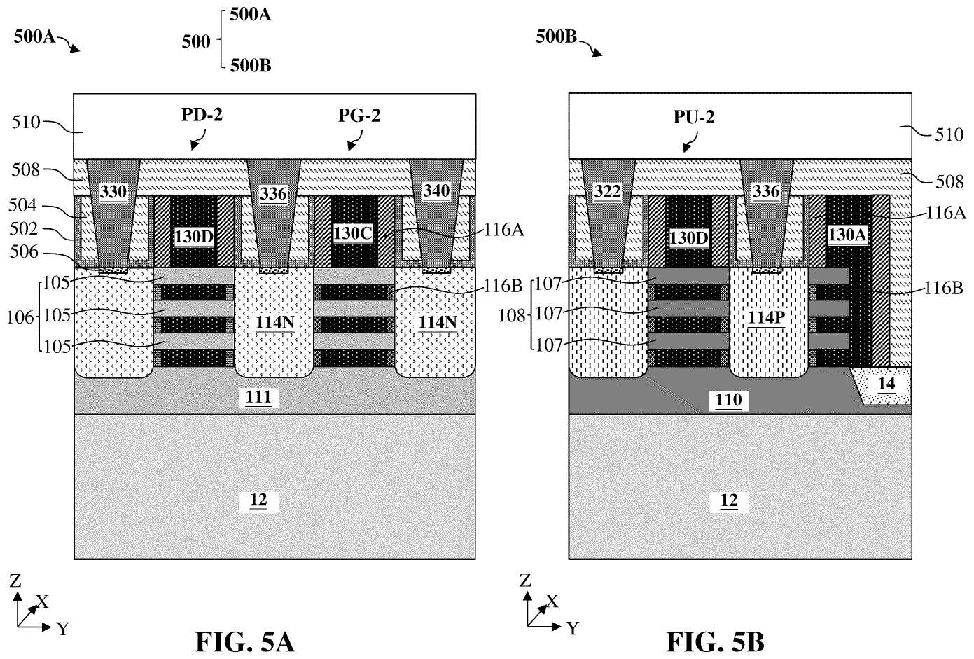

Method for forming the backside butted contact 328 is described with reference to FIGS. 4, 5A-12A, and 5B-12B. FIG. 4 illustrates a flowchart of an exemplary method for fabricating a memory cell, such as an SRAM cell, according to various embodiments of the present disclosure. FIGS. 5A-12A depict cross-sectional views of the SRAM cell 101 taken along line A-A as shown in FIGS. 3A and 3D during various fabrication stages in the method of FIG. 4, according to various aspects of the present disclosure, and FIGS. 5B-12B depict cross-sectional views of the SRAM cell 101 taken along line B-B as shown in FIGS. 3A and 3D during various fabrication stages in the method of FIG. 4, according to various aspects of the present disclosure.

Referring now to FIGS. 4 and 5A-5B, method 400 includes a block 402 where a workpiece 500 is received. The workpiece 500 includes a first device region 500A and a second device region 500B. In the present embodiments, the first device region 500A includes one or more n-type GAA transistors (e.g., PD-2 and PG-2) formed in and over the p-well 111 in the substrate 12, and the second device region 500B includes one or more p-type GAA transistors (e.g., PU-2) formed on and over the n-well 110 in the substrate 12. In the present embodiments, the substrate 12 includes silicon. Alternatively, or additionally, the substrate 12 includes another elementary semiconductor, such as germanium; a compound semiconductor, such as silicon carbide, silicon phosphide, gallium arsenide, gallium phosphide, indium phosphide, indium arsenide, and/or indium antimonide; an alloy semiconductor, such as SiGe, SiPC, GaAsP, AlInAs, AlGaAs, GaInAs, GaInP, and/or GaInAsP; or combinations thereof. In some embodiments, the substrate 12 is a semiconductor-on-insulator substrate, such as a silicon-on-insulator (SOI) substrate, a silicon germanium-on-insulator (SGOI) substrate, or a germanium-on-insulator (GOI) substrate. Semiconductor-on-insulator substrates can be fabricated using separation by implantation of oxygen (SIMOX), wafer bonding, other suitable methods, or combinations thereof. Each n-well 110 may be doped with an n-type dopant, such as phosphorus, arsenic, other n-type dopants, or combinations thereof. Each p-well 111 may be doped with a p-type dopant, such as boron, indium, other p-type dopants, or combinations thereof. In some embodiments, the substrate 12 includes doped regions formed with a combination of p-type dopants and n-type dopants. The various doped regions can be formed directly on and/or in the substrate 12, for example, providing a p-well structure, an n-well structure, a dual-well structure, a raised structure, or combinations thereof. Each of the various doped regions may be formed by performing an ion implantation process, a diffusion process, other suitable doping processes, or combinations thereof.

The first device region 500A includes a p-type fin 106. The p-type fin 106 includes a number of (e.g., three) channel layers 105. The first device region 500A also includes gate structures (e.g., gate structures 130D and 130C) formed over channel regions of the p-type fin 106. In the present embodiments, each gate structure 130C/130D wraps around and over each channel layers 105 of the p-type fin 106. The first device region 500A also includes n-type source/drain features 114N formed in the p-well 111 and coupled to the channel layers 105. Source/drain feature(s) may refer to a source or a drain, individually or collectively dependent upon the context. Exemplary n-type source/drain features 114N may include silicon, phosphorus-doped silicon, arsenic-doped silicon, antimony-doped silicon, or other suitable material and may be in-situ doped during the epitaxial process by introducing an n-type dopant, such as phosphorus, arsenic, or antimony, or ex-situ doped using a junction implant process.

The second device region 500B includes n-type fin 108. The n-type fin 108 includes a number of (e.g., three) channel layers 107. The second device region 500B also includes gate structures (e.g., gate structures 130D and 130A) formed over channel regions of the n-type fin 108. In the present embodiments, each gate structure 130A/130D wraps around and over each channel layers 107 of the n-type fin 108. The second device region 500B also includes p-type source/drain features 114P formed in the n-well 110 and coupled to the channel layers 107. Exemplary p-type source/drain features 114P may include germanium, gallium-doped silicon germanium, boron-doped silicon germanium, or other suitable material and may be in-situ doped during the epitaxial process by introducing a p-type dopant, such as boron or gallium, or ex-situ doped using a junction implant process. In some embodiments, the n-type source/drain features 114N and/or the p-type source/drain features 114P each may be a multi-layer structure that includes an undoped semiconductor layer, a lightly doped semiconductor layer, and a heavily doped semiconductor layer.

The formation of the transistors PD-2, PG-2, PU-2 represented in FIGS. 5A-5B may include forming vertical stacks of alternating channel layers 105/107 (e.g., Si) and sacrificial layers (e.g., SiGe, not shown) over the substrate 12; patterning the vertical stacks and a top portion of the substrate 12 to form fin-shaped active regions; forming the isolation structures 14 (e.g., shallow trench isolation (STI), field oxide, local oxidation of silicon (LOCOS) to insulate various components formed over the substrate 12; forming dummy gate structures over channel regions of the fin-shaped active regions; forming the inner spacers 116B; forming the n-type source/drain features 114N and the p-type source/drain features 114P in and over source/drain regions of the fin-shaped active regions; selectively removing the dummy gate structures, selectively removing the sacrificial layers to release the channel layers 105/107; and forming gate dielectric layer and metal gate electrode of the gate structures (e.g., gate structures 130A-130D) to wrap around and over the channel layers 105/107.

In the present embodiments, each gate structure 130A-130D includes at least the high-k gate dielectric layer and the metal gate electrode. In the present embodiments, portions of the high-k gate dielectric layer wrap around each channel layer, such that each gate structure 130A-130D engages with the plurality of channel layers in each GAA transistor. The high-k gate dielectric layer may include silicon oxynitride, aluminum silicon oxide, a high-k dielectric material such as hafnium oxide, zirconium oxide, lanthanum oxide, titanium oxide, yttrium oxide, strontium titanate, other suitable dielectric materials, or combinations thereof. Though not depicted, each metal gate electrode may further include a bulk conductive layer disposed over at least one work function metal layer. The bulk conductive layer may include Cu, W, Ru, Co, Al, Ti, Ta, other suitable metals, or combinations thereof. In some examples, each gate structure may include one or more work function metal layer of the same conductivity type or of different conductivity types. Examples of the work function metal layers may include TiN, TaN, Ru, Mo, Al, WN, ZrSi₂, MoSi₂, TaSi₂, NiSi₂, Ti, Ag, TaAl, TaAlC, TiAlN, TaC, TaCN, TaSiN, Mn, Zr, other suitable work function materials, or combinations thereof. Various work function metal layers may be first deposited and then patterned to satisfy different requirements of threshold voltage in different GAA FETs. Additional material layers may also be included in each gate structure, such as an interfacial layer, a barrier layer, a capping layer, other suitable materials layers, or combinations thereof. Various layers of the gate structures may be deposited by any suitable method, such as chemical oxidation, thermal oxidation, atomic layer deposition (ALD), chemical vapor deposition (CVD), physical vapor deposition (PVD), plating, other suitable methods, or combinations thereof. Each gate structure 130A-130D may further include top spacers 116A and inner spacers 116B disposed on its sidewalls, where the top spacers 116A are disposed over the channel layers 105 and 107 and the inner spacers 116B are disposed in the space between two vertically stacked channel layers 105 or two vertically stacked channel layers 107.

Still referring to FIGS. 5A-5B, the workpiece 500 also includes a contact etch stop layer (CESL) 502 and an interlayer dielectric (ILD) layer 504 deposited over the n-type source/drain features 114N and the p-type source/drain features 114P. The CESL 502 may include silicon nitride, silicon oxynitride, and/or other materials known in the art and may be formed by ALD, plasma-enhanced chemical vapor deposition (PECVD) process and/or other suitable deposition or oxidation processes. As shown in FIGS. 5A-5B, the CESL 502 may be deposited on top surfaces of the n-type source/drain features 114N and the p-type source/drain features 114P and sidewalls of the top spacers 116A. The ILD layer 504 may be deposited by a PECVD process or other suitable deposition technique after the deposition of the CESL 502. The ILD layer 504 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials.

The workpiece 500 also includes a dielectric layer 508 formed over the gate structures 130A-130D. The formation and composition of the dielectric layer 508 may be similar to those of the ILD layer 504. The workpiece 500 also includes frontside source/drain contacts (e.g., frontside source/drain contacts 302, 308, 314, 316, 322, 330, 336, 340) extending through the dielectric layer 508, the ILD layer 504, and the CESL 502. In embodiments represented in FIGS. 5A-5B, each of the frontside source/drain contacts 330, 336, 340 and 322 are formed over the source/drain features 114N/114P and electrically coupled to the respective source/drain feature 114N/114P via a silicide layer 506. The frontside source/drain contacts 330, 336, 340 and 322 may include any suitable conductive material, such as Cu, W, Ru, Co, Al, Ti, Ta, other suitable metals, or combinations thereof. Each S/D contact 330, 336, 340 and 322 may further include a barrier layer comprising any suitable material, such as Ti, Ta, TiN, TaN, other suitable materials, or combinations thereof. In some embodiments, the silicide layer 506 may include nickel silicide, titanium silicide, cobalt silicide, other suitable silicides, or combinations thereof. Gate vias 320 and 344 are not shown in FIGS. 5A and 5B, but it is understood that, in some embodiments, gate vias 320 and 344 may extend through the dielectric layer 508 and electrically coupled to its respective gate structure thereunder.

The workpiece 500 also includes a MLI structure 510 formed over the front side of the workpiece 500. Because the MLI structure 510 is formed over the front side of the workpiece 500, the MLI structure 510 may also be referred to as a frontside MLI structure 510. As provided herein, the MLI structure 510 may include a number of conductive features (e.g., metal lines and/or vias) configured to interconnect various components of the SRAM cells 101 with additional features to ensure the proper performance of the IC structure 10. The conductive features of the MLI structure 510 may be disposed in and/or separated by intermetal dielectric (IMD) layers. The conductive features of the MLI structure 510 may include the frontside source/drain vias (e.g., frontside source/drain vias 304, 310, 318, 324, 332, 342) that are formed on the frontside source/drain contacts (e.g., frontside source/drain contacts 302, 308, 314, 316, 322, 330, 336) and metal lines/contacts (e.g., 300a, 300b, 300c, 300d, 300e, 300f, 300g, 300i) formed on or over the frontside source/drain vias or the gate vias. Each conductive feature of the MLI structure 510 may be formed of metal, such as aluminum, tungsten, ruthenium, or copper. In some embodiments, each conductive feature may be lined by a barrier layer to insulate the metal lines and contact vias from the IMD layers and to prevent electro-migration. Each IMD layer may include a low-k dielectric material, silicon oxide, other suitable dielectric materials, or combinations thereof, and may be formed by spin-on-glass, flowable CVD (FCVD), other suitable methods, or combinations thereof.

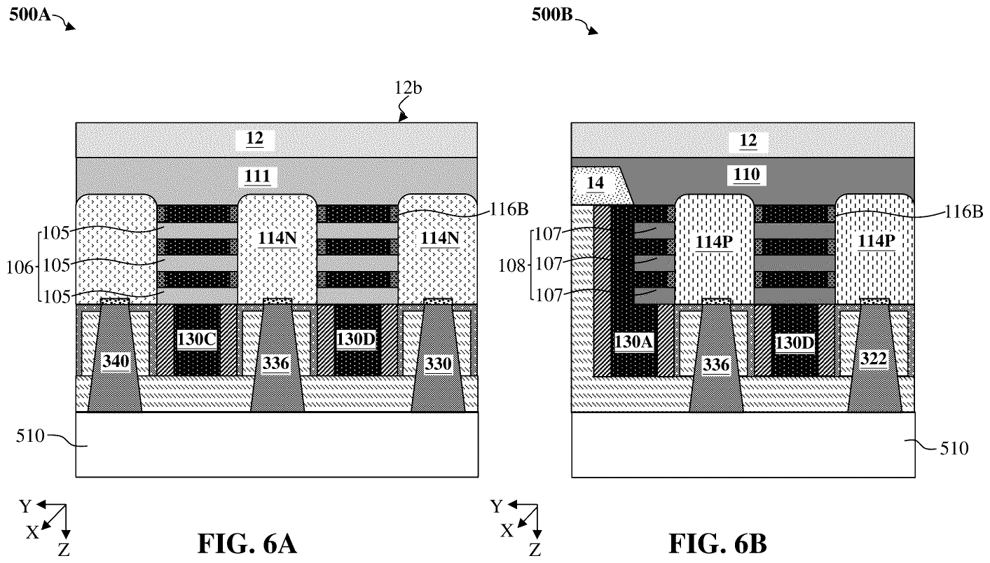

Referring to FIGS. 4 and 6A-6B, method 400 includes a block 404 where the workpiece 500 is flipped over. In some embodiments, a carrier substrate may be bonded to the MLI structure 510 and the workpiece 500 is then flipped over. In some embodiments, the carrier substrate may be bonded to the workpiece 500 by fusion bonding, by use of an adhesion layer, or a combination thereof. In some instances, the carrier substrate may include semiconductor materials (such as silicon), sapphire, glass, polymeric materials, or other suitable materials. Once the carrier substrate is bonded to the MLI structure 510, the workpiece 500 is flipped over. The carrier substrate may be then removed. As shown in FIGS. 6A-6B, after the workpiece 500 is flipped over, the substrate 12 is disposed over the channel layers 105 and 107.

Referring to FIGS. 4 and 6A-6B, method 400 includes a block 406 where the substrate 12 is thinned down from its backside. After the workpiece 500 is flipped over, a thinning process may be performed to thin the substrate 12 from its backside to reduce a total thickness of the workpiece 500. The thinning process may include a mechanical grinding process and/or a chemical thinning process. For example, a substantial amount of substrate material may be removed from the substrate 12 during a mechanical grinding process. After the thinning down process, the substrate 12 has a bottom surface 12b.

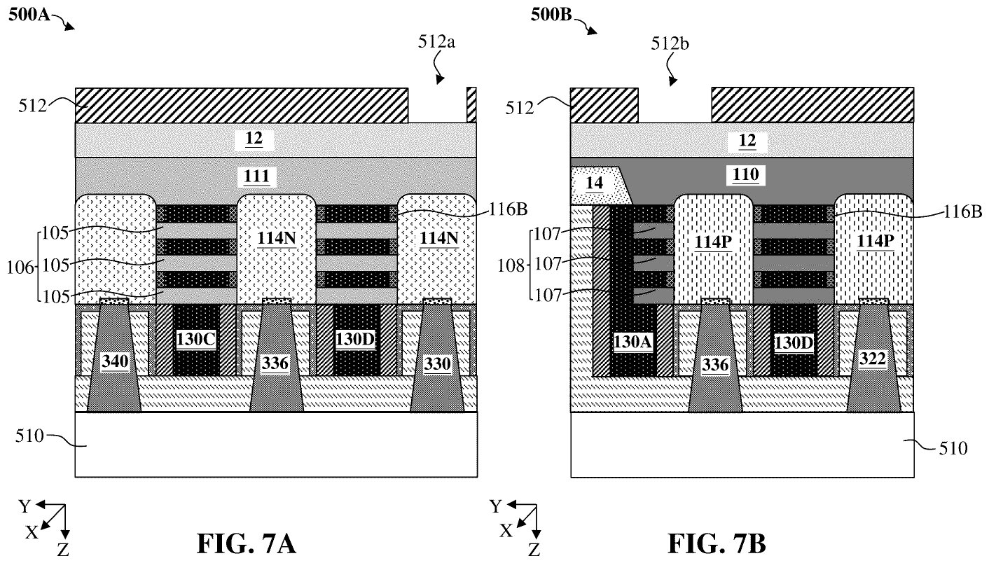

Referring to FIGS. 4 and 7A-7B, method 400 includes a block 408 where a patterned mask film 512 is formed on the bottom surface 12b of the substrate 12. A mask film may be first deposited on the bottom surface 12b of the substrate 12 using CVD or ALD and then a photoresist layer (not shown) is deposited over the mask film using spin-on coating or other suitable processes. The photoresist layer may be patterned using photolithography process to form a patterned photoresist layer. The patterned photoresist layer is then applied as an etch mask in an etching process to pattern the mask film, thereby forming the patterned mask film 512. The patterned photoresist layer may be selectively removed after the formation of the patterned mask film 512. In embodiments represented in FIGS. 7A-7B, the patterned mask film 512 includes a first opening 512a directly over the source/drain feature 114N in the first device region 500A and a second opening 512b directly over the gate structure 130A and the source/drain feature 114P in the second device region 500B. The patterned mask film 512 may include silicon oxide, silicon nitride, silicon oxynitride, silicon oxycarbonitride, silicon carbide, or silicon oxycarbide. In an embodiment, the patterned mask film 512 is formed of silicon nitride.

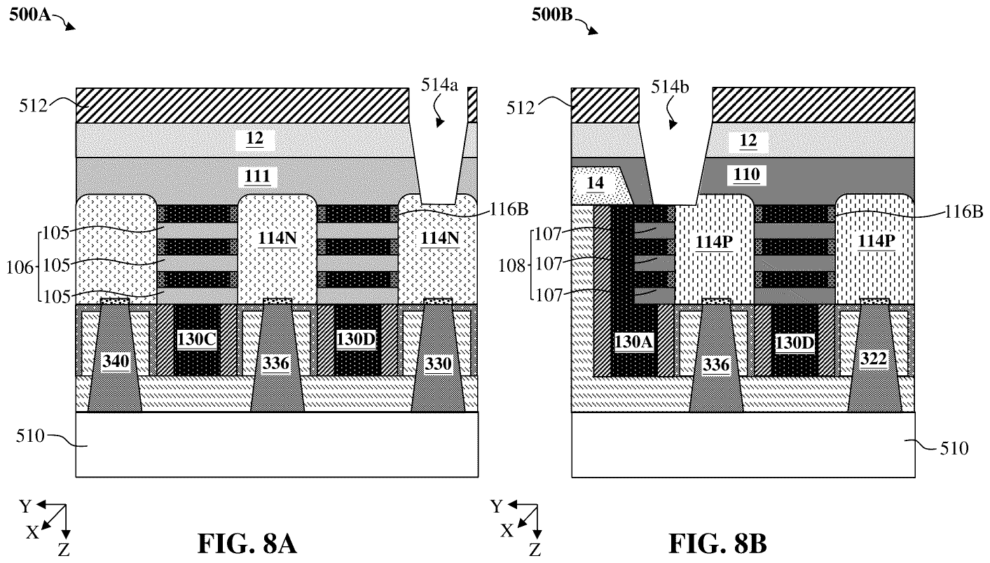

Referring to FIGS. 4 and 8A-8B, method 400 includes a block 410 where a first trench 514a is formed to expose the source/drain feature 114N in the first device region 500A and a second trench 514b is formed to expose the gate structure 130A and the source/drain feature 114P in the second device region 500B. While using the patterned mask film 512 as an etch mask, an etching process is performed to the workpiece 500 to form the first trench 514a and the second trench 514b. In some implementations, the etching process may be a dry etching process. An exemplary dry etching process may implement an oxygen-containing gas, hydrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. In embodiments represented in FIG. 8B, the second trench 514b exposes a bottom surface of the gate structure 130A and extends into the source/drain feature 114P.

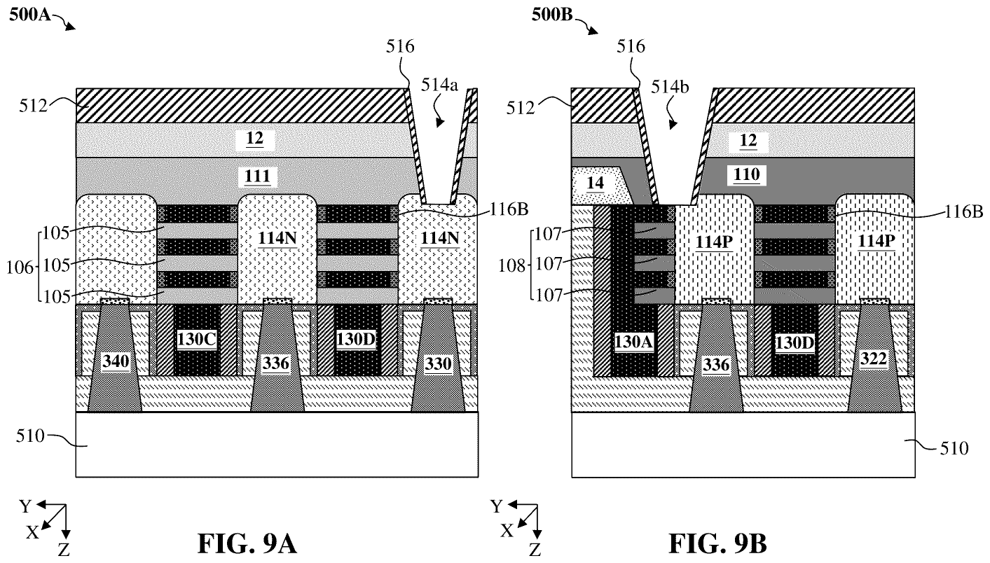

Referring to FIGS. 4 and 9A-9B, method 400 includes a block 412 where dielectric liners 516 are formed in the first trench 514a and the second trench 514b. As shown in FIGS. 9A-9B, after the formation of the first trench 514a and the second trench 514b, in some embodiments, a dielectric barrier layer is deposited over the workpiece 500 and is then etched back to only cover sidewalls of the first trench 514a and the second trench 514b and expose the source/drain feature 114N in the first device region 500A, and the source/drain feature 114P and gate structure 130A in the second device region 500B. The etched back dielectric barrier layer may be referred to as dielectric liners 516. In some embodiments, the dielectric liners 516 may include silicon nitride or other suitable materials. In embodiments represented in FIG. 9A, the dielectric liners 516 extend along the substrate 12 and disposed directly on the source/drain feature 114N in the first device region 500A. In embodiments represented in FIG. 9B, the dielectric liners 516 extend along the substrate 12 and disposed directly on the source/drain feature 114P and the gate structure 130A in the second device region 500B.

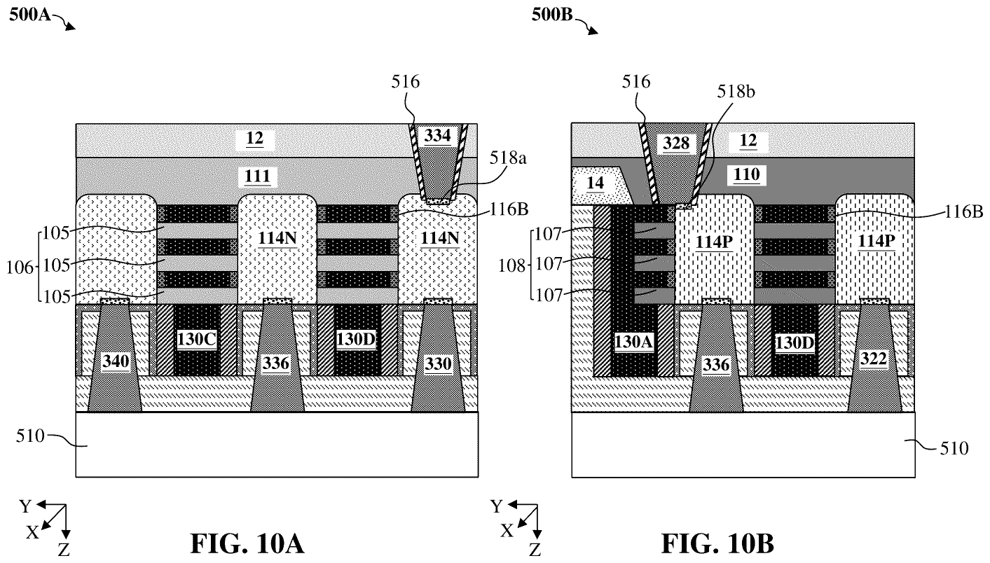

Referring to FIGS. 4 and 10A-10B, method 400 includes a block 414 where silicide layers 518a and 518b are formed in the first trench 514a and the second trench 514b, respectively. After forming the dielectric liners 516, a silicide layer 518a is formed on the exposed surface of the source/drain feature 114N in the first device region 500A to reduce a contact resistance between the source/drain feature 114N and the to-be-formed backside source/drain via 334, and a silicide layer 518b is formed on the exposed surface of the source/drain feature 114P in the second device region 500B to reduce a contact resistance between the source/drain feature 114P and the to-be-formed backside butted contact 328. To form the silicide layers 518a and 518b, a metal layer (not explicitly shown) is deposited over the bottom surface of the workpiece 500 and an anneal process is performed to bring about silicidation reaction between the metal layer and the source source/drain features 114N and 114P. Suitable metal layer may include titanium, tantalum, nickel, cobalt, or tungsten. The silicide layers 518a and 518b generally track the shape of the exposed source/drain features 114N and 114P, respectively. Excessive metal layer that does not form the source/drain features 114N and 114P may be removed.

Referring to FIGS. 4 and 10A-10B, method 400 includes a block 416 where a backside source/drain via 334 is formed in the first trench 514a and a backside butted contact 328 is formed in the second trench 514b. The formation of the backside source/drain via 334 and the backside butted contact 328 may include depositing a conductive layer (e.g., aluminum, rhodium, ruthenium, copper, iridium, or tungsten) over the bottom surface of the workpiece 500 to fill the first trench 514a and the second trench 514b and performing a planarization process (e.g., chemical mechanical polish (CMP) process) to remove excess materials and the patterned mask film 512. The backside source/drain via 334 is electrically coupled to the source/drain feature 114N in the first device region 500A by way of the silicide layer 518a. In other words, the silicide layer 518a is sandwiched between the source/drain feature 114N and the backside source/drain via 334. The backside butted contact 328 is electrically coupled to the source/drain feature 114P and the gate structure 130A in the second device region 500B. More specifically, the backside butted contact 328 is in direct contact with a bottom surface of the gate structure 130A. The backside butted contact 328 also directly contacts the silicide layer 518b. That is, the silicide layer 518b is disposed vertically between the backside butted contact 328 and the source/drain feature 114P. In the present embodiments, the backside butted contact 328 is in direct contact with a bottommost inner spacer of those inner spacers 116B.

Referring to FIGS. 4 and 11A-11B, method 400 includes a block 418 where a backside power rail 522 is formed to electrically couple to the backside source/drain via 334. A backside dielectric layer 520 is formed over the bottom surface of the workpiece 500. A composition of the dielectric layer 520 is similar to the composition of the ILD layer 504. A backside power rail trench (filled by the backside power rail 522) may be then formed in the dielectric layer 520 to expose the backside source/drain via 334 in the first device region 500A. After forming the backside power rail trench, a barrier layer and a metal fill material are then deposited into the power rail trench to form the backside power rail 522. In an embodiment, the backside power rail 522 may be the Vss′ line 300g. In some embodiments, the barrier layer in the backside power rail 522 may include titanium nitride, tantalum nitride, cobalt nitride, nickel nitride, or tungsten nitride and the metal fill material in the backside power rail 522 may include titanium, ruthenium, copper, nickel, cobalt, tungsten, tantalum, or molybdenum. The barrier layer and the metal fill layer may be deposited using PVD, CVD, ALD, or electroless plating. A planarization process, such as a CMP process, may be performed to remove excess materials over the dielectric layer 520. In some embodiments, a backside MLI structure may be formed under the bottom surface of the workpiece 500. In the above embodiments, the backside butted contact 328 is formed along with the backside source/drain via 334. In some other implementations, the backside butted contact 328 and the backside source/drain via 334 may be formed in any sequential order. In embodiments where the SRAM cell doesn't include a backside source/drain via, and the backside butted contact 328 may be formed separately in accordance with method 400 described with reference to FIG. 4.

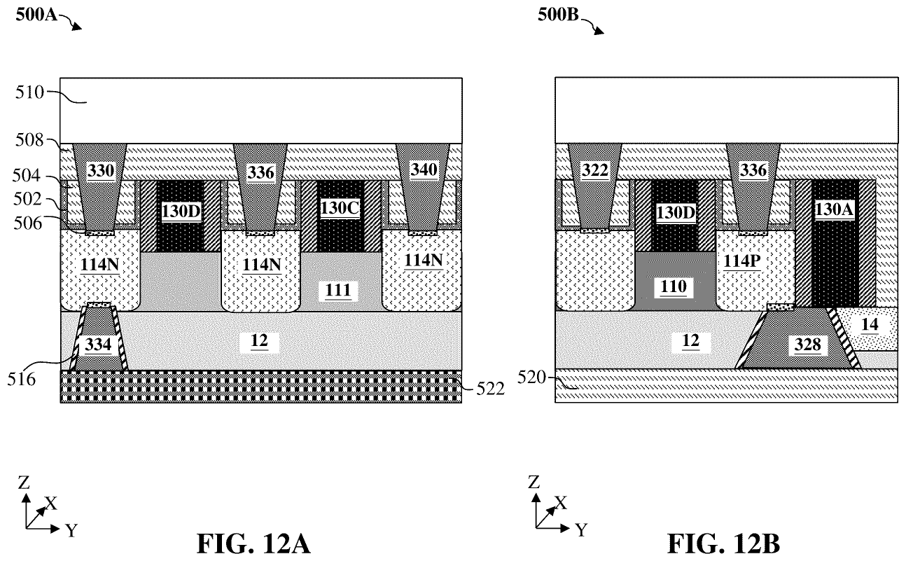

In the above embodiments, SRAM cell 101 is implemented using GAA transistors. In some other embodiments, SRAM cell 101 may be implemented using “planar” transistors or FinFETs. For example, in embodiments represented in FIGS. 12A and 12B, SRAM cell having FinFETs includes a backside source/drain via 334 electrically coupled to the source/drain feature 114N in the first device region 500A and further includes a backside butted contact 328 in direct contact with a portion of a bottom surface of the gate structure 130A disposed adjacent to the source/drain feature 114P. The backside butted contact 328 is also electrically coupled to the source/drain feature 114P by way of a silicide layer. As such, the gate structure 130A and the source/drain feature 114P are electrically connected. Method for forming the butted contact for FinFET-based SRAM cell may be similar to the method 400 and is omitted for reason of simplicity.

An alternative method 600 for forming the backside butted contact 328 is described with reference to FIGS. 13, 14A-17A and 14B-17B. More specifically, after performing the operations in block 406 of method 400, method 600 is followed. In the present embodiment, the workpiece 500 shown in FIGS. 6A and 6B is referred to as a workpiece 700. The workpiece 700 includes a first device region 700A that is the same as the first device region 500A represented in FIG. 6A and a second device region 700B that is the same as the second device region 500B represented in FIG. 6B.

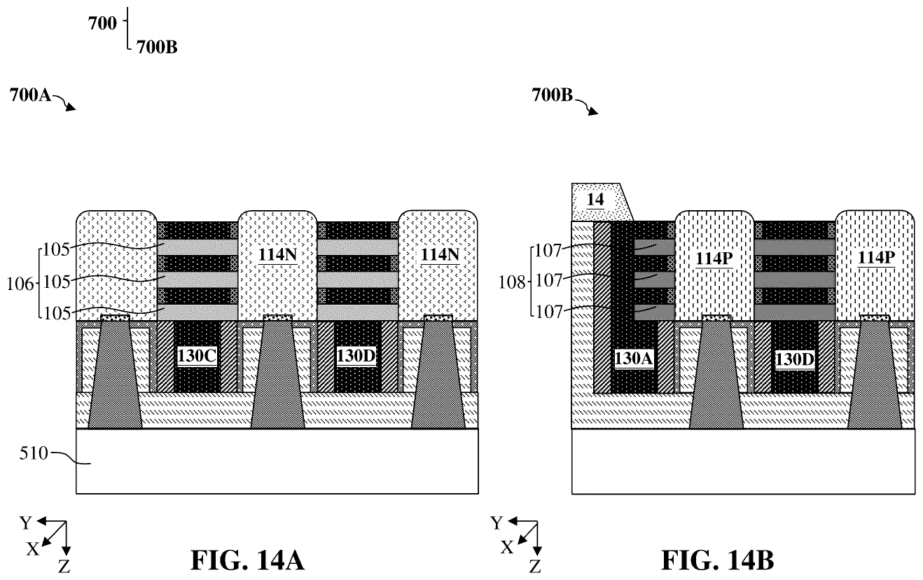

Referring to FIGS. 13 and 14A-14B, after flipping over the workpiece 700, operations in block 602 of method 600 is performed. That is, the substrate 12 is selectively removed. In some embodiments, the substrate 12 may be selectively removed by a selective etching process, such as a selective wet etching process or a selective dry etching process. An exemplary selective dry etching process may implement CF₄, NF₃, Cl₂, HBr, other suitable gases and/or plasmas, and/or combinations thereof. As shown in FIGS. 14A-14B, the selective removal at block 602 does not substantially damage the gate structures 130A, 130C, 130D, the isolation structure 14, and the source/drain features 114N/114P.

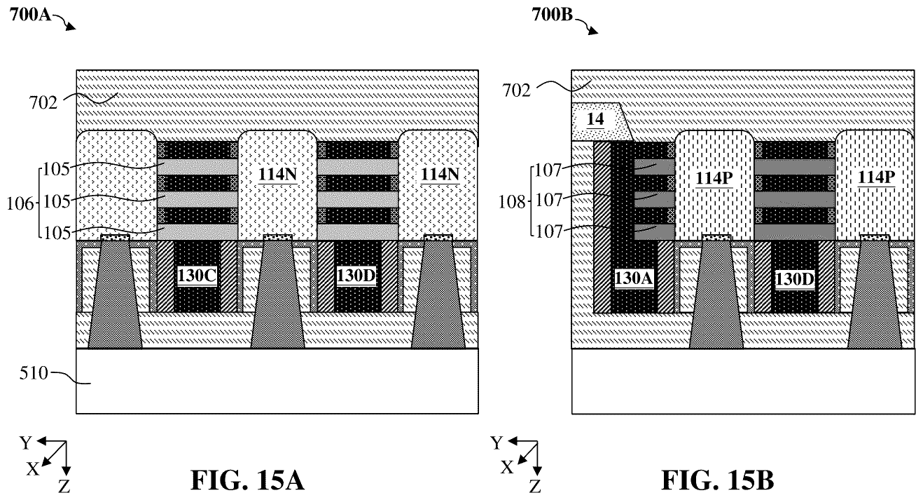

Referring to FIGS. 13 and 15A-15B, method 600 includes a block 604 where a backside dielectric layer 702 is deposited over the bottom surface of the workpiece 700. The backside dielectric layer 702 may be deposited over the back side of the workpiece 700 by FCVD, CVD, PECVD, spin-on coating, or a suitable process. In some instances, the dielectric layer 702 may include silicon oxide or have a composition similar to that of the ILD layer 504. A planarization process, such as a CMP process, may be performed to planarize the back side of the workpiece 700, thereby providing a planar surface.

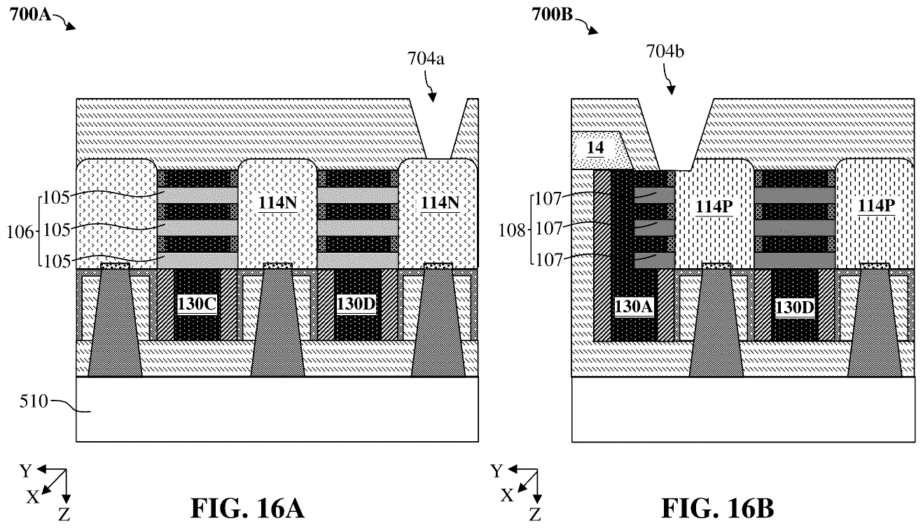

Referring to FIGS. 13 and 16A-16B, method 600 includes a block 606 where a first trench 704a is formed in the first device region 700A and a second trench 704b is formed in the second device region 700B. The formation of the first trench 704a and the second trench 704b may be similar to the formation of the first trench 514a and the second trench 514b. For example, a patterned mask film that is similar to the patterned mask film 512 may be formed over the back side of the workpiece 700, and an etching process may be performed to remove portions of the backside dielectric layer 702 to form the first trench 704a and the second trench 704b. The first trench 704a extends through the backside dielectric layer 702 and exposes a bottom surface of the source/drain feature 114N in the first device region 700A, and the second trench 704b extends through the backside dielectric layer 702 and exposes a bottom surface of the gate structure 130A and extends into source/drain feature 114P in the second device region 700B. That is, the second trench 704b exposes both the gate structure 130A and the source/drain feature 114P.

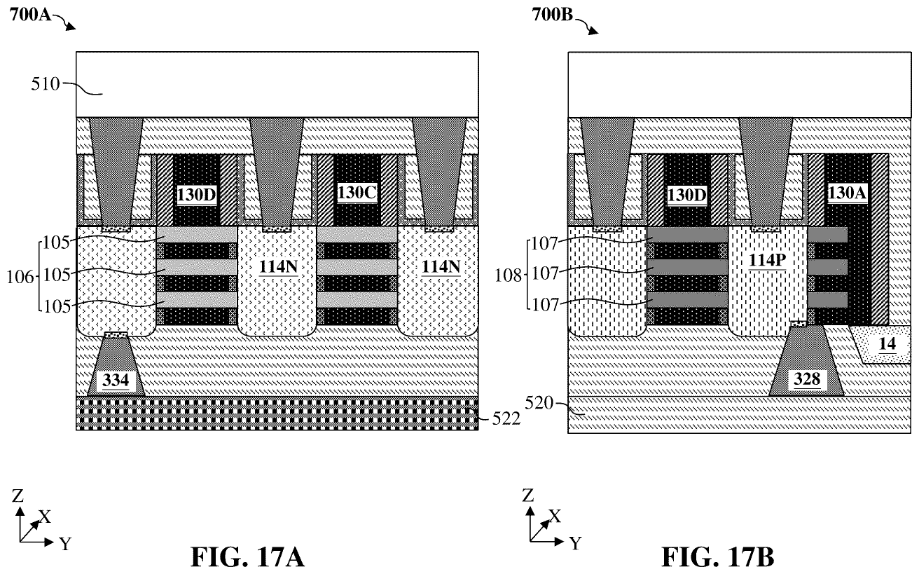

Referring to FIGS. 13 and 17A-17B, after forming the first trench 704a and the second trench 704b, operations in blocks 414, 416, 418 of method 400 are performed to form the silicide layers 518a-518b, backside source/drain via 334, the backside butted contact 328, and the backside power rail 522 to finish the fabrication of the workpiece 700. In embodiments represented in FIGS. 11A-11B, the backside source/drain via 334 is spaced apart from the backside dielectric layer 702 by the dielectric liners 516, and the backside butted contact 328 is spaced apart from the backside dielectric layer 702 by the dielectric liners 516. In embodiments represented in FIGS. 17A-17B, since the backside butted contact 328 and the backside source/drain via 334 are embedded in the backside dielectric layer 702, dielectric liners 516 may be omitted.

Although not intended to be limiting, one or more embodiments of the present disclosure provide many benefits to an IC structure and the formation thereof. For example, the present embodiments provide an array of memory cells, such as SRAM cells, in an IC structure, where each SRAM cell includes n-type GAA transistors, such as pull-down transistors and pass-gate transistors, formed over p-type fins and p-type GAA transistors, such as pull-up transistors, formed over n-type fins, and where each of the p-type fins and n-type fins includes a stack of semiconductor (channel) layers engaged with a gate structure. In the present embodiments, electrical connection between a gate structure of one transistor and a source/drain feature of another transistor is achieved by forming a backside butted contact feature. The backside butted contact feature is disposed under the source/drain feature and the gate structure. Forming the butted contact under the source/drain feature and the gate structure would increase a contact area between the butted contact and the gate structure and a contact area between the butted contact and the source/drain feature, thereby providing a better connection. Forming the butted contact under the source/drain feature would release room that would be otherwise occupied by a frontside butted contact, thus, design flexibility of metal lines that are disposed over the source/drain feature and adjacent to the frontside butted contact may be increased. Also, leakage or short issue associated with frontside butted contacts may be alleviated.

The present disclosure provides for many different embodiments. Semiconductor structures and methods of fabrication thereof are disclosed herein. In one exemplary aspect, the present disclosure is directed to an integrated circuit (IC) structure. The integrated circuit (IC) structure includes a channel region over a substrate, a source/drain feature coupled to the channel region, a gate structure engaging the channel region, and a first contact feature electrically coupled to the source/drain feature and the gate structure, where a first portion of the first contact feature is disposed directly under the gate structure.

In some embodiments, a second portion of the first contact feature may be disposed directly under the source/drain feature. In some embodiments, the IC structure may also include a first silicide layer, where the first contact feature may be spaced apart from the source/drain feature by the first silicide layer. In some embodiments, the IC structure may also include a second silicide layer, a frontside dielectric layer over the source/drain feature, and a second contact feature extending through the frontside dielectric layer and disposed directly over the source/drain feature, where the second contact feature may be spaced apart from the source/drain feature by the second silicide layer. In some embodiments, the IC structure may also include a metal line disposed over and electrically coupled to the second contact feature, where the metal line may be disposed directly over the first contact feature. In some embodiments, a shape of a top view of the metal line may include a rectangular shape. In some embodiments, the channel region may include a plurality of nanostructures, and the gate structure may wrap around each of the plurality of nanostructures. In some embodiments, the IC structure may also include inner spacer features disposed between the gate structure and the source/drain feature, where a third portion of the first contact feature may be disposed directly under one of the inner spacer features. In some embodiments, the IC structure may also include a dielectric liner extending along a sidewall surface of the first contact feature, where the first contact feature may be spaced apart from the substrate by the dielectric liner.

In another exemplary aspect, the present disclosure is directed to an integrated circuit (IC) structure. The integrated circuit (IC) structure includes first and second fins extending lengthwise in a first direction and over a substrate, first and second gate structures extending lengthwise in a second direction perpendicular to the first direction, wherein the first gate structure engages the first fin in forming a first transistor, the second gate structure engages the second fin in forming a second transistor, and the second gate structure is in contact with a terminal end of the first fin, a first source/drain feature of the first transistor, and a first backside contact structure disposed under the first source/drain feature of the first transistor and electrically coupled to the second gate structure and the first source/drain feature of the first transistor.

In some embodiments, the IC structure may also include a first silicide layer disposed under the first source/drain feature of the first transistor, where the first backside contact structure may be in direct contact with the first silicide layer and a bottom surface of the second gate structure. In some embodiments, the IC structure may also include a second silicide layer disposed on the first source/drain feature of the first transistor, and a frontside contact structure in direct contact with the second silicide layer. In some embodiments, the IC structure may also include a first source/drain feature of the second transistor, and a second backside contact structure disposed under the first source/drain feature of the second transistor and electrically coupled to the first gate structure and the source/drain feature of the second transistor. In some embodiments, the IC structure may also include a second source/drain feature of the first transistor, a second source/drain feature of the second transistor, and a metal line electrically coupled to the second source/drain feature of the first transistor and the second source/drain feature of the second transistor, where the metal line may extend lengthwise along the first direction and has a uniform width. In some embodiments, the metal line may be vertically overlapped with the first backside contact structure. In some embodiments, the IC structure may also include a dielectric liner extending along sidewalls of the first backside contact structure, where the first backside contact structure may be spaced apart from the substrate by the dielectric liner.

In yet another exemplary aspect, the present disclosure is directed to a method. The method includes providing a workpiece including a channel region over a substrate, a source/drain feature coupled to the channel region, and a gate structure engaging the channel region. The method also includes flipping over the workpiece, after the flipping over of the workpiece, performing an etching process, thereby forming an opening extending through the substrate, where bottom surfaces of the source/drain feature and the gate structure are exposed in the opening, and forming a contact feature in the opening, where the contact feature is electrically coupled to the source/drain feature and the gate structure.

In some embodiments, the contact feature may be in direct contact with the bottom surface of the gate structure. In some embodiments, the contact feature may be spaced apart from the source/drain feature by a silicide layer. In some embodiments, the method may also include, before the forming of the contact feature, forming a dielectric liner along sidewalls of the opening, where the contact feature may be spaced apart from the substrate by the dielectric liner.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) structure, comprising:
a channel region over a substrate;
a source/drain feature coupled to the channel region;
a gate structure comprising a first portion over the channel region and a second portion under the first portion; and
a contact feature electrically coupled to the source/drain feature and the gate structure,
wherein a portion of the contact feature extends on a bottom surface of the second portion of the gate structure.

2. The IC structure of claim 1, wherein another portion of the contact feature is disposed under the source/drain feature.

3. The IC structure of claim 1, further comprising:
a silicide layer under the source/drain feature,
wherein the contact feature is spaced apart from the source/drain feature by the silicide layer.

4. The IC structure of claim 3, wherein the silicide layer is a first silicide layer, and the contact feature is a first contact feature, wherein the IC structure further comprises:
a second silicide layer on the source/drain feature,
a second contact feature over the source/drain feature and coupled to the second silicide layer,
wherein the second contact feature is spaced apart from the source/drain feature by the second silicide layer.

5. The IC structure of claim 4, further comprising:
a metal line disposed over and electrically coupled to the second contact feature,
wherein the metal line extends over the first contact feature.

6. The IC structure of claim 1, further comprising:
another channel region coupled to the source/drain feature,
wherein the two channel regions have different widths.

7. The IC structure of claim 1, wherein the channel region comprises a plurality of nanostructures, and the second portion of the gate structure wraps around the plurality of nanostructures.

8. The IC structure of claim 7, further comprising:
inner spacer features disposed between the gate structure and the source/drain feature,
wherein the contact feature is vertically overlapped with one of the inner spacer features.

9. The IC structure of claim 1, further comprising:
a dielectric liner extending along a sidewall surface of the contact feature,
wherein the contact feature is spaced apart from the substrate by the dielectric liner.

10. An integrated circuit (IC) structure, comprising:
first and second fin-shaped structures extending lengthwise along a first direction and over a substrate;
a first gate structure extending lengthwise along a second direction different from to the first direction, wherein the first gate structure extends over the first and second fin-shaped structures, wherein the first gate structure and the first fin-shaped structure are portions of a first transistor,
a second gate structure extending lengthwise along the second direction, wherein the second gate structure extends over the first and second fin-shaped structures, wherein the second gate structure and the second fin-shaped structure are portions of a second transistor, and the second gate structure terminates near an end of the first fin-shaped structure;
a source/drain feature of the first transistor; and
a backside contact structure disposed under and electrically coupled to the second gate structure and the source/drain feature.

11. The IC structure of claim 10, further comprising:
a silicide layer disposed under the source/drain feature,
wherein the backside contact structure is in direct contact with the silicide layer and disposed under a bottom surface of the second gate structure.

12. The IC structure of claim 11, further comprising:
another silicide layer disposed on the source/drain feature; and
another contact structure formed over the source/drain feature and electrically coupled to the another silicide layer.

13. The IC structure of claim 10, further comprising:
a source/drain feature of the second transistor; and
another backside contact structure disposed under the source/drain feature of the second transistor and electrically coupled to the first gate structure and the source/drain feature of the second transistor.

14. The IC structure of claim 10, further comprising:
an isolation feature adjacent to the end of the first fin-shaped structure;
wherein a portion of the second gate structure is landed on the isolation feature.

15. The IC structure of claim 14, wherein a height of the backside contact structure is greater than a height of the isolation feature.

16. The IC structure of claim 10, further comprising:
a dielectric liner extending along sidewalls of the backside contact structure,
wherein the backside contact structure is spaced apart from the substrate by the dielectric liner.

17. A semiconductor structure, comprising:
an active region comprising a source/drain feature disposed between a first channel region and a second channel region;
a first gate structure over the first channel region;
a second gate structure over the second channel region;
a source/drain contact over and electrically coupled to the source/drain feature; and
a conductive feature under and electrically coupled to both the source/drain feature and the second gate structure.

18. The semiconductor structure of claim 17, further comprising:
a first gate spacer extending along a first sidewall of the second gate structure; and
a second gate spacer extending along a second sidewall of the second gate structure opposite the first sidewall, wherein a height of the second gate spacer is greater than a height of the first gate spacer.

19. The semiconductor structure of claim 17, wherein a width of the first channel region is greater than a width of the second channel region.

20. The semiconductor structure of claim 17, wherein the second channel region comprises a plurality of nanostructures, and the second gate structure further comprises a first portion wrapping around the plurality of nanostructures and a second portion disposed laterally adjacent to the plurality of nanostructures.
